(19) United States
(12) Patent Application Publication
(10) Pub. No.: US 2019/0215954 A1
(43) Pub. Date: Jul. 11, 2019

(54) POSITIONING STRUCTURE AND FLEXIBLE PRINTED CIRCUIT

(71) Applicant: Kunshan Go-Visionox Opto-Electronics Co., Ltd., Kunshan (CN)

(72) Inventors: Tan ZHANG, Kunshan (CN); Zhan SUN, Kunshan (CN)

(73) Assignee: Kunshan Go-Visionox Opto-Electronics Co., Ltd.

(21) Appl. No.: 16/355,476

(22) Filed: Mar. 15, 2019

Related U.S. Application Data
(63) Continuation of application No. PCT/CN2018/084881, filed on Apr. 27, 2018.

(30) Foreign Application Priority Data
Aug. 23, 2017 (CN) 201721062229.3

(51) Int. Cl. H05K 1/02; H05K 1/03; H05K 3/46

(52) U.S. Cl. CPC H05K 1/0281; H05K 2201/2027; H05K 3/4679; H05K 1/0366

(57) ABSTRACT

Embodiments of the present disclosure provide a positioning structure and a flexible printed circuit. The positioning structure includes a flexible substrate having a positioning hole therein and a reinforcing layer disposed on the flexible substrate and located within a preset range around a periphery of the positioning hole to reinforce the positioning hole, and the reinforcing layer includes a first hole corresponding to the positioning hole. In the positioning structure according to the embodiments of the present disclosure, the strength of the positioning hole is improved and an undesirable deformation phenomenon of the positioning hole under action of external forces is prevented, by disposing the positioning hole on the flexible substrate and laying the reinforcing layer in the preset range around the periphery of the positioning hole.

### CROSS-REFERENCE TO RELATED APPLICATIONS

This application is a continuation of International Application No. PCT/CN2018/084881 filed on Apr. 27, 2018, which claims priority to Chinese patent application No. 201721062229.3 filed on Aug. 23, 2017. Both applications are incorporated herein by reference in their entireties.

### TECHNICAL FIELD

Embodiments of the present disclosure relate to the field of bonding technology, and in particular to a positioning structure and a flexible printed circuit.

### BACKGROUND

A flexible printed circuit is a printed circuit board made of a flexible insulating substrate, and is capable of being bent, wound and folded freely. The flexible printed circuit is available in single-sided, multi-sided and multi-layer boards and other types, and it is mainly formed by laying a cover film with mechanical protection and good electrical insulation properties on a surface of the flexible insulating substrate and pressing the cover film to the surface of the flexible insulating substrate.

However, in an existing FOF (i.e., FPC ON FPC, Flexible Printed Circuit bonding Flexible

Printed Circuit) process, because a material around a positioning hole of the flexible printed circuit is soft and weak, the positioning hole is prone to deformation under action of a positioning device force and other external forces, and the deformed positioning hole may result in inaccurate positioning and even result in bonding failure of the flexible printed circuit during a positioning process.

### SUMMARY

In view of this, embodiments of the present disclosure provide a positioning structure and a flexible printed circuit, in order to solve the problem that the positioning hole is easily deformed under action of external forces.

In a first aspect, a positioning structure according to an embodiment of the present disclosure includes a flexible substrate having a positioning hole therein and a reinforcing layer disposed on the flexible substrate and located within a preset range around a periphery of the positioning hole to reinforce the positioning hole, and the reinforcing layer includes a first hole corresponding to the positioning hole.

In an embodiment of the present disclosure, the reinforcing layer includes a hard layer. The hard layer is disposed on the flexible substrate and is located within the preset range around the periphery of the positioning hole, and the hard layer has a second hole aligned with the positioning hole.

In an embodiment of the present disclosure, the reinforcement layer further includes a protective film disposed on the flexible substrate and located within the preset range around the periphery of the positioning hole, and the hard layer is partially or entirely covered by the protective film.

In an embodiment of the present disclosure, the positioning hole is circular-shaped, the protective film is annular-shaped, and the hard layer is annular-shaped.

In an embodiment of the present disclosure, the hard layer includes a plurality of segments, and the segments are annularly distributed along the periphery of the positioning hole.

In an embodiment of the present disclosure, the positioning hole is circular-shaped, the protective film is annular-shaped, and each of the plurality of segments is one of or a combination of a circular shape, a fan shape, a semicircular shape, and an irregular shape.

In an embodiment of the present disclosure, the reinforcing layer further includes a protective film disposed on the flexible substrate and located within a preset range around the hard layer, and an inner periphery of the protective film coincides with an outer periphery of the hard layer.

In an embodiment of the present disclosure, the hard layer includes a metal plating layer or a hard coating layer or a strengthening layer.

In an embodiment of the present disclosure, a distance between an outer periphery of the reinforcing layer and a periphery of the positioning hole is in a range of 0 mm to 10 mm.

In a second aspect, a flexible printed circuit according to an embodiment of the present disclosure includes an electronic device; and the positioning structure according to the above embodiments of the present disclosure.

In the positioning structure according to the embodiments of the present disclosure, the strength of the positioning hole is improved and an undesirable deformation phenomenon of the positioning hole under action of external forces is prevented, by disposing the positioning hole on the flexible substrate and laying the reinforcing layer in the preset range around the periphery of the positioning hole.

### BRIEF DESCRIPTION OF DRAWINGS

FIG. 1 is a structural schematic diagram of a positioning structure according to a first embodiment of the present disclosure.

FIG. 2 is a structural schematic diagram of a positioning structure according to a second embodiment of the present disclosure.

FIG. 3 is a structural schematic diagram of a positioning structure according to a third embodiment of the present disclosure.

FIG. 4 is a structural schematic diagram of a positioning structure according to a fourth embodiment of the present disclosure.

FIG. 5 is a structural schematic diagram of a positioning structure according to a fifth embodiment of the present disclosure.

FIG. 6 is a structural schematic diagram of a positioning structure according to a sixth embodiment of the present disclosure.

### DETAILED DESCRIPTION

In order to make objects, technical means and advantages of the present disclosure more comprehensible, the present disclosure is to be further described in detail below with reference to accompanying drawings. The advantages and features of the present disclosure will be more apparent according to following description and claims. It may be noted that the accompanying drawings are all in a very simplified form and all use non-precise proportions, so as to conveniently and clearly state embodiments of the present disclosure.

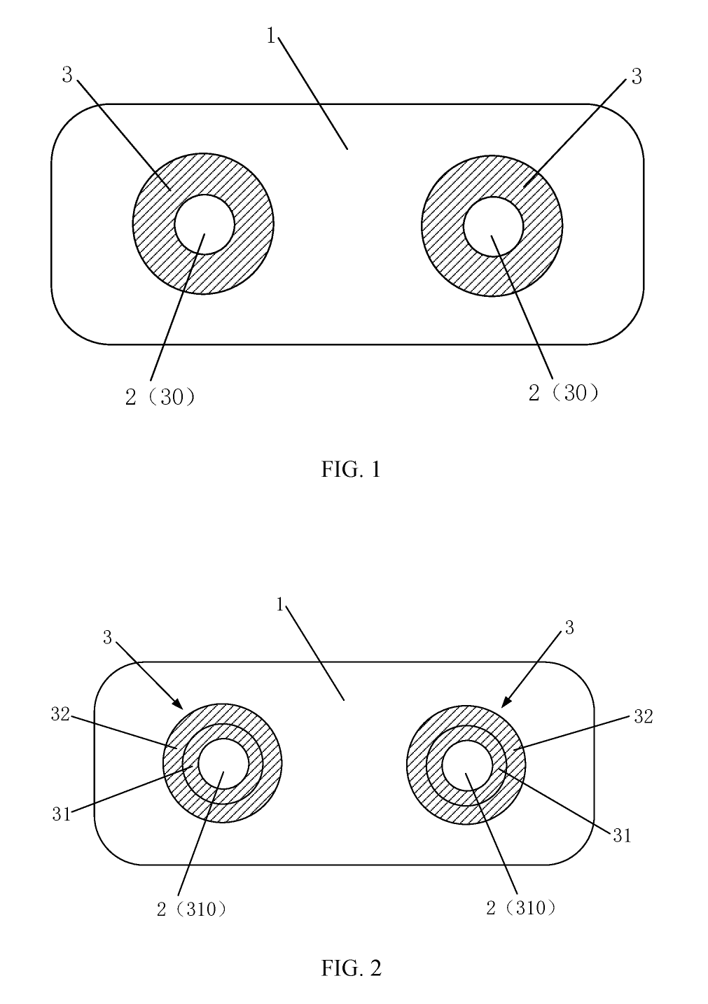

FIG. 1 is a structural schematic diagram of a positioning structure according to a first embodiment of the present disclosure. As shown in FIG. 1, the positioning structure according to the first embodiment of the present disclosure includes a flexible substrate 1 having positioning holes 2 therein and reinforcing layers 3. The reinforcing layers 3 are disposed on the flexible substrate 1 and are located within preset ranges around peripheries of the positioning holes 2 to reinforce the positioning holes 2. The reinforcing layers 3 have first holes 30 corresponding to the positioning holes 2.

In the positioning structure according to the first embodiment of the present disclosure, the positioning holes 2 are disposed on the flexible substrate 1 and the reinforcing layers 3 are laid in the preset ranges around the peripheries of the positioning holes 2. Therefore, the strength of the positioning holes 2 is improved and an undesirable deformation phenomenon of the positioning holes 2 under action of external forces is prevented.

It may be understood that one of the first holes 30 in the reinforcing layers 3 may be the same size as the positioning hole 2 that corresponds to the first hole 30 or may be larger than the positioning hole 2.

It may be understood that the preset ranges in which the reinforcing layers 3 are disposed around the peripheries of the positioning holes 2 may be freely set according to an actual condition. For example, the preset ranges may be set from 0 mm to 10 mm, that is, distances between outer peripheries of the reinforcing layers 3 and the peripheries of the positioning holes 2 are in a range of 0 mm to 10 mm, which will improve functions of the reinforcing layers 3 without impacting structures around the positioning holes 2. In addition, a size of one of the preset ranges may also be set according to the size of the positioning hole 2 that corresponds to the reinforcing layer 3. For example, the larger a radius of the positioning hole 2, the larger the preset range is.

It may be understood that the sizes and shapes of the positioning holes 2 formed on the flexible substrate 1 may be freely set according to the actual condition. For example, the positioning holes 2 are set to be circular holes with the radius of 5 mm, and the embodiments of the present disclosure are not limited to this. Instead, the shapes of the positioning holes 2 may also be square or oval.

It may be understood that the reinforcing layers 3 may be disposed on an upper and/or a lower surface of the flexible substrate 1 on which the positioning holes 2 are formed, so as to substantially enhance the expansibility and the adaptability of the positioning structure according to the embodiments of the present disclosure.

In an embodiment of the present disclosure, one of the reinforcing layers 3 is an annulate strip, an inner periphery of the reinforcing layer 3 coincides with the periphery of the positioning hole 2 that corresponds to the reinforcing layer 3. With arranging the reinforcing layer 3 as the annulate strip, the positioning hole 2 is fixed sufficiently by the reinforcing layer 3 and material cost and resources are saved at the same time. It may be understood that a shape of one of the reinforcing layers 3 may also be set according to the shape of the positioning hole 2 that corresponds to the reinforcing layer 3. For example, when the shape of the positioning hole 2 is square, the reinforcing layer 3 may be a square ring, and when the shape of the positioning hole 2 is elliptical, the reinforcing layer 3 may be an elliptical ring. It may be understood that the shape of the reinforcing layer 3 may also be different from the shape of the positioning hole 2. For example, when the shape of the positioning hole 2 is circular-shaped, the reinforcing layer 3 may be a square ring.

It may be understood that the shape of one of the reinforcing layers 3 may be set freely according to the actual condition. For example, the reinforcing layer 3 may include a plurality of segments, and the plurality of segments are annularly distributed along the periphery of the positioning hole 2 that corresponds to the reinforcing layer 3 so as to reinforce the positioning hole 2. In addition, shapes of the segments may be freely set according to the actual condition, and the shapes of the segments include one or a combination of following shapes: a diamond shape, a circle shape, a fan shape and so on.

In an embodiment of the present disclosure, the flexible substrate 1 is a flexible printed circuit. In an actual application process, when a Driver Flexible Printed Circuit (Driver FPC) and a Touch Panel Flexible Printed Circuit (TP FPC) are required to be bonded to achieve electrical conduction, positioning holes 2 of the Driver FPC and/or positioning holes 2 of the TP FPC are subjected to a treatment of laying the reinforcing layers 3 on an upper and/or a lower surface, so as to sufficiently increase the strength and the hardness of the positioning holes 2, and make the positioning holes 2 on the flexible printed circuit sufficiently adapt to different actual conditions and usage requirements. Therefore, the adaptability and the expansibility of the positioning structure according to the embodiments of the present disclosure are increased.

In an embodiment of the present disclosure, materials of the reinforcing layers 3 include, but are not limited to, a polyimide film, a cover film, a cover layer and other materials, which have both insulation protection and reinforcing effects. In addition, it may be understood that each reinforcing layer 3 may include one or more sublayers, and the number of the sublayers and materials of the sublayers may be set freely according to the actual condition.

According to the first embodiment of the present disclosure, in the actual application process, the positioning holes 2 are formed in the flexible substrate 1, and the reinforcing layers 3 are disposed on the peripheries of the positioning holes 2 of at least one surface of the flexible substrate 1. Therefore, the strength and the hardness of the peripheries of the positioning holes 2 are strengthened, so as to prevent the positioning holes 2 from being deformed by the external forces.

FIG. 2 is a structural schematic diagram of a positioning structure according to a second embodiment of the present disclosure. As shown in FIG. 2, the positioning structure according to the second embodiment of the present disclosure is substantially the same as the positioning structure according to the first embodiment of the present disclosure. The following only highlights differences, and similarities are not repeated here. One of reinforcing layers 3 in the positioning structure according to the second embodiment of the present disclosure includes a hard layer 31 and a protective film 32, and the hard layer 31 and the protective film 32 are laid on a same surface of a flexible substrate 1. An inner periphery of the hard layer 31 coincides with a periphery of a positioning hole 2. The protective film 32 is attached to a side of the hard layer 31 that is away from the positioning hole 2 that corresponds to the reinforcing layer 3, and the hard layer 31 is partially or entirely covered by the protective film 32. That is, the protective film 32 is disposed on the flexible substrate 1 and is located within a preset range around the hard layer 31.

In an embodiment of the present disclosure, the hard layer 31 is an annulate strip, and an inner periphery of the hard layer 31 coincides with the periphery of the positioning hole 2 that corresponds to the hard layer 31.

In an embodiment of the present disclosure, the hard layer 31 is a metal plating layer made of a copper foil.

In an embodiment of the present disclosure, the hard layer 31 is a metal plating layer made of an aluminum foil.

In an embodiment of the present disclosure, the hard layer 31 is a sprayed hard coating layer.

In an embodiment of the present disclosure, the hard layer 31 is a strengthening layer.

In an embodiment of the present disclosure, a material of the strengthening layer includes, but is not limited to, a cover film or a cover layer, etc., which have both insulation protection and reinforcing effects. In addition, it may be understood that each strengthening layer may include one or more sublayers, and the number of the sublayers and the materials of the sublayers may be set freely according to an actual condition.

In an embodiment of the present disclosure, the protective film 32 also has functions of avoiding oxidation of the hard layer 31, covering for a subsequent surface treatment, and acting as a solder resist in subsequent Surface Mount Technology (SMT).

In an actual application process, the positioning holes 2 are formed in the flexible substrate 1, and the hard layers 31 are laid on peripheries of the positioning holes 2 of at least one surface of the flexible substrate 1. The protective films 32 are laid on sides of the hard layers 31 which are away from the flexible substrate 1. An inner periphery of one of the protective films 32 and the inner periphery of the hard layer 31 that corresponds to the protective film 32 are coincided, and an outer periphery of the protective film 32 is larger than an outer periphery of the hard layer 31.

In the positioning disclosure according to the second embodiment of the present disclosure, the positioning holes 2 are formed on the flexible substrate 1, the reinforcing layers 3 are laid along the peripheries of the positioning holes 2, one of the reinforcing layers 3 includes the hard layer 31 and the protective film 32, and the hard layer 31 and the protective film 32 are laid on the same surface of the flexible substrate 1, the inner periphery of the hard layer 31 and the periphery of the positioning hole 2 that corresponds to the hard layer 31 are coincided, the protective film 32 is attached to the side of the hard layer 31 that is away from the positioning hole 2, and the hard layer 31 is partially or entirely covered by the protective film 32. Therefore, the strength of the positioning holes 2 is improved, an undesirable deformation of the positioning holes 2 under external forces is prevented, and positioning accuracy decrease of the positioning holes 2 caused by the undesirable deformation of the positioning holes 2 is avoided.

In an embodiment of the present disclosure, one of the reinforcing layers 3 contains the hard layer 31 and excludes the protective film 32. The hard layer 31 is disposed on the flexible substrate 1 and is located within a preset range around the periphery of the positioning hole 2 that corresponds to the reinforcing layer 3. The hard layer 31 has a second hole 310 aligned with the positioning hole 2. In the positioning structure according to the embodiments of the present disclosure, the strength of the positioning hole 2 is improved by means of the hard layer 31, so as to avoid the undesirable deformation of the positioning hole 2 under the external forces.

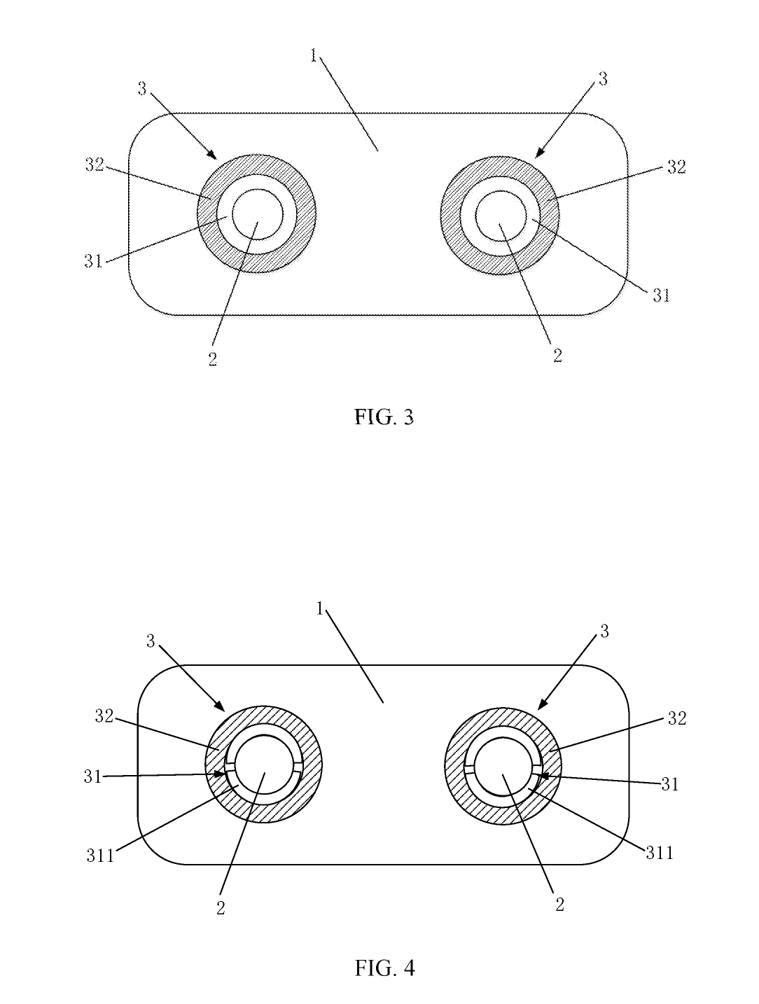

FIG. 3 is a structural schematic diagram of a positioning structure according to a third embodiment of the present disclosure. As shown in FIG. 3, the positioning structure according to the third embodiment of the present disclosure is substantially the same as the positioning structure according to the first embodiment of the present disclosure. The following only highlights differences, and similarities are not repeated here. One of reinforcing layers 3 in the positioning structure according to the third embodiment of the present disclosure includes a hard layer 31 and a protective film 32, and the hard layer 31 and the protective film 32 are laid on a same surface of a flexible substrate 1. An inner periphery of the hard layer 31 coincides with a periphery of a positioning hole 2 that corresponds to the reinforcing layer 3, and an inner periphery of the protective film 32 coincides with an outer periphery of the hard layer 31.

In an embodiment of the present disclosure, the hard layer 31 is an annulate strip, and the inner periphery of the hard layer 31 coincides with the periphery of the positioning hole 2.

In an embodiment of the present disclosure, the hard layer 31 is a metal plating layer made of a copper foil.

In an embodiment of the present disclosure, the hard layer 31 is a metal plating layer made of an aluminum foil.

In an embodiment of the present disclosure, the hard layer 31 is a sprayed hard coating layer.

In an actual application process, the positioning holes 2 are formed in the flexible substrate 1, and the hard layers 31 are laid on the peripheries of the positioning holes 2 of at least one surface of the flexible substrate 1. The protective films 32 are laid on sides of the hard layers 31 which are away from the flexible substrate 1, the inner periphery of one of the protective films 32 and an outer periphery of the hard layer 31 that corresponds to the protective film 32 are coincided.

In the positioning structure according to the third embodiment of the present disclosure, the positioning holes 2 are formed on the flexible substrate 1, the reinforcing layers 3 are laid along the peripheries of the positioning holes 2, one of the reinforcing layers 3 includes the hard layer 31 and the protective film 32, and the hard layer 31 and the protective film 32 are laid on the same surface of the flexible substrate 1, the inner periphery of the hard layer 31 and the periphery of the positioning hole 2 that corresponds to the hard layer 31 are coincided, the protective film 32 is attached to the side of the hard layer 31 that is away from the positioning hole 2, the inner periphery of the protective film 32 and the outer periphery of the hard layer 31 are coincided. Therefore, the strength of the positioning holes 2 is improved, an undesirable deformation of the positioning holes 2 under external forces is prevented, and positioning accuracy decrease of the positioning holes 2 caused by the undesirable deformation of the positioning holes 2 is avoided.

FIG. 4 is a structural schematic diagram of a positioning structure according to a fourth embodiment of the present disclosure. As shown in FIG. 4, the positioning structure according to the fourth embodiment of the present disclosure is substantially the same as the positioning structure according to the third embodiment of the present disclosure. The following only highlights differences, and similarities are not repeated here. One of hard layers 31 in the positioning structure according to the fourth embodiment of the present disclosure includes two semicircular annulate strips 311, and the two semicircular annulate strips 311 are evenly distributed along a periphery of a positioning hole 2 that corresponds to the hard layer 31, inner peripheries of the two semicircular annulate strips 311 and the periphery of the positioning hole 2 are coincided.

In the positioning structure according to the fourth embodiment of the present disclosure, the positioning holes 2 are formed on a flexible substrate 1, reinforcing layers 3 are laid along the peripheries of the positioning holes 2, one of the reinforcing layers 3 includes the hard layer 31 and a protective film 32, the hard layer 31 and the protective film 32 are laid on a same surface of the flexible substrate 1, the hard layer 31 is set as the two semicircular annulate strips 311 which are distributed evenly along the periphery of the positioning hole 2, the inner peripheries of the two semicircular annulate strips 311 and the periphery of the positioning hole 2 are coincided, the protective film 32 is attached to a side of the hard layer 31 that is away from the positioning hole 2, an inner periphery of the protective film 32 and an outer periphery of the hard layer 31 are coincided. Therefore, the strength of the positioning holes 2 is improved, an undesirable deformation of the positioning holes 2 under external forces is prevented, and positioning accuracy decrease of the positioning holes 2 caused by the undesirable deformation of the positioning holes 2 is avoided.

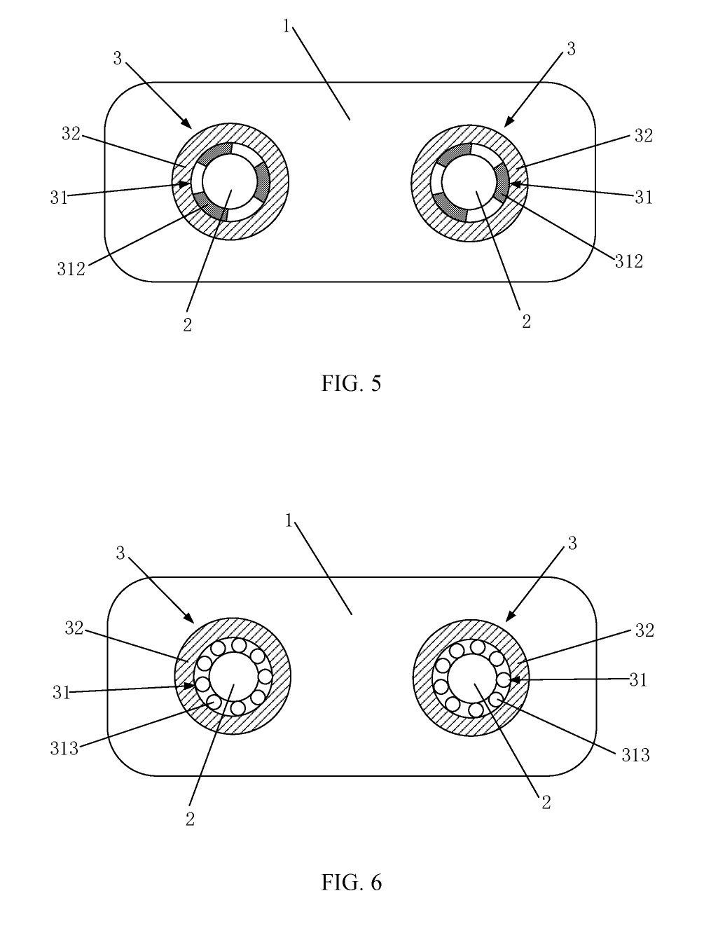

FIG. 5 is a structural schematic diagram of a positioning structure according to a fifth embodiment of the present disclosure. As shown in FIG. 5, the positioning structure according to the fifth embodiment of the present disclosure is substantially the same as the positioning structure according to the third embodiment of the present disclosure. The following only highlights differences, and similarities are not repeated here. One of hard layers 31 in the positioning structure according to the fifth embodiment of the present disclosure includes three fanning strips 312, and the three fanning strips 312 are evenly and annularly distributed along a periphery of a positioning hole 2 that corresponds to the hard layer 31. A fan-shaped gap is included between two adjacent strips 312, inner peripheries of the three fanning strips 312 and the periphery of the positioning hole 2 are coincided.

In the positioning structure according to the fifth embodiment of the present disclosure, the positioning holes 2 are formed on a flexible substrate 1, reinforcing layers 3 are laid along the peripheries of the positioning holes 2, one of reinforcing layers 3 includes the hard layer 31 and a protective film 32, and the hard layer 31 and the protective film 32 are laid on a same surface of the flexible substrate 1, the hard layer 31 is set as the three fanning strips 312 which are annular distributed evenly along the periphery of the positioning hole 2, the inner peripheries of the three fanning strips 312 and the periphery of the positioning hole 2 are coincided, the protective film 32 is attached to a side of the hard layer 31 that is away from the positioning hole 2, an inner periphery of the protective film 32 and an outer periphery of the hard layer 31 are coincided. Therefore, the strength of the positioning holes 2 is improved, an undesirable deformation of the positioning holes 2 under external forces is prevented, and positioning accuracy decrease of the positioning holes 2 caused by the undesirable deformation of the positioning holes 2 is avoided.

FIG. 6 is a structural schematic diagram of a positioning structure according to a sixth embodiment of the present disclosure. As shown in FIG. 6, the positioning structure according to the sixth embodiment of the present disclosure is substantially the same as the positioning structure according to the third embodiment of the present disclosure. The following only highlights differences, and similarities are not repeated here. One of hard layers 31 in the positioning structure according to the sixth embodiment of the present disclosure includes a plurality of circular strips 313, and the plurality of circular strips 313 are evenly and annularly distributed along a periphery of a positioning hole 2 that corresponds to the hard layer 31.

In the positioning structure according to the sixth embodiment of the present disclosure, the positioning holes 2 are formed on a flexible substrate 1, reinforcing layers 3 are laid along the peripheries of the positioning holes 2, one of the reinforcing layers 3 includes the hard layer 31 and a protective film 32, the hard layer 31 and the protective film 32 are laid on a same surface of the flexible substrate 1, the hard layer 31 is set as the plurality of circular strips 313 which are annular distributed evenly along the periphery of the positioning hole 2, the protective film 32 is attached to a side of the hard layer 31 that is away from the positioning hole 2, an inner periphery of the protective film 32 and an outer periphery of the hard layer 31 are coincided. Therefore, the strength of the positioning holes 2 is improved, an undesirable deformation of the positioning holes 2 under external forces is prevented, and positioning accuracy decrease of the positioning holes 2 caused by the undesirable deformation of the positioning holes 2 is avoided.

It may be understood that shapes of the hard layers 31 may be set freely according to an actual condition. For example, one of the hard layers 31 may include a plurality of segments. Shapes of the segments in the hard layer 31 may be set freely according to the actual condition, and are not limited to the shape mentioned in the above embodiments of the present disclosure. For example, the shapes of the segments in the hard layer 31 may be elliptical shapes or irregular shapes.

It may be understood that the number of the positioning holes 2 may also be one, and the embodiments of the present disclosure does not uniformly limit the number of positioning holes 2.

The foregoing descriptions are merely preferred embodiments of the present disclosure, but the protection scope of the present disclosure is not limited hereto. Any modifications, equivalent replacements or improvements, etc. made within the spirit and principles of the present disclosure are intended to be included in the scope of protection of the present disclosure.

What is claimed is:

1. A positioning structure, comprising:
a flexible substrate having a positioning hole; and
a reinforcing layer disposed on the flexible substrate and located within a preset range around a periphery of the positioning hole to reinforce the positioning hole, the reinforcing layer including a first hole corresponding to the positioning hole.

2. The positioning structure of claim 1, wherein the reinforcing layer comprises a hard layer disposed on the flexible substrate and located within the preset range around the periphery of the positioning hole, and the hard layer includes a second hole aligned with the positioning hole.

3. The positioning structure of claim 2, wherein the reinforcing layer further comprises a protective film disposed on the flexible substrate and located within the preset range around the periphery of the positioning hole, and the hard layer is partially or entirely covered by the protective film.

4. The positioning structure of claim 3, wherein the positioning hole is circular-shaped, the protective film is annular-shaped, and the hard layer is annular-shaped.

5. The positioning structure of claim 3, wherein the hard layer comprises a plurality of segments, and the plurality of segments are annularly distributed along the periphery of the positioning hole.

6. The positioning structure of claim 5, wherein the positioning hole is circular-shaped, the protective film is annular-shaped, and each of the plurality of segments is one of or a combination of a circular shape, a fan shape, a semicircular shape and an irregular shape.

7. The positioning structure of claim 2, wherein the reinforcing layer further comprises a protective film disposed on the flexible substrate and located within a preset range around the hard layer, and an inner periphery of the protective film coincides with an outer periphery of the hard layer.

8. The positioning structure of claim 7, wherein the positioning hole is circular-shaped, the protective film is annular-shaped, and the hard layer is annular-shaped.

9. The positioning structure of claim 7, wherein the hard layer comprises a plurality of segments, and the plurality of segments are annularly distributed along the periphery of the positioning hole.

10. The positioning structure of claim 9, wherein the positioning hole is circular-shaped, the protective film is annular-shaped, and each of the plurality of segments is one of or a combination of a circular shape, a fan shape, a semicircular shape, and an irregular shape.

11. The positioning structure of claim 2, wherein the hard layer comprises a metal plating layer or a hard coating layer or a strengthening layer.

12. The positioning structure of claim 1, wherein a distance between an outer periphery of the reinforcing layer and a periphery of the positioning hole is in a range of 0 mm to 10 mm.

13. A flexible printed circuit, comprising:
an electronic device; and
the positioning structure according to claim 1.
